(19) United States
(12) Patent Application Publication
(10) Pub. No.: US 2022/0279639 A1
(43) Pub. Date: Sep. 1, 2022

(54) LIGHTING DEVICE

(71) Applicant: Ushio Lighting, Inc., Tokyo (JP)

(72) Inventor: Tatsuya MOTOIKE, Tokyo (JP)

(73) Assignee: Ushio Lighting, Inc., Tokyo (JP)

(21) Appl. No.: 17/632,200

(22) PCT Filed: Jun. 23, 2020
(86) PCT No.: PCT/JP2020/024618

§ 371 Date: Feb. 1, 2022

(30) Foreign Application Priority Data
Sep. 3, 2019 (JP) 2019-160142

(51) Int. Cl. H05B 47/105; H01S 5/06; H01S 5/024

(52) U.S. Cl. CPC H05B 47/105; H01S 5/0612; H01S 5/02453

(57) ABSTRACT

Provided is a lighting device using semiconductor laser elements that can be safely used even in a cold region etc. The present invention includes: a plurality of semiconductor laser elements; a temperature sensor that measures an ambient temperature of the plurality of semiconductor laser elements; and a current controller that controls current supply to the semiconductor laser elements, wherein, when a measured value from the temperature sensor is equal to or less than a predetermined first threshold temperature, the current controller does not supply a current equal to or greater than a threshold current, which is required to emit laser light, to the semiconductor laser elements until the measured value exceeds the first threshold temperature, and when the measured value exceeds the first threshold temperature, the current controller supplies a current equal to or greater than the threshold current to the semiconductor laser elements.

### TECHNICAL FIELD

The present invention relates to a lighting device, and more particularly relates to a lighting device using a semiconductor laser element.

### BACKGROUND ART

In recent years, a lighting device using a semiconductor laser element (also referred to as “LD”) having a longer life than a discharge lamp, higher output than a light emitting diode (also referred to as “LED”), and better light directivity has been developed. The applicant of the present invention has been developing a lighting device, etc. that combine semiconductor laser elements and phosphor elements, as described in the following Patent Document 1.

### CITATION LIST

### Patent Document

Patent Document 1: JP-A-2018-6133

### SUMMARY OF INVENTION

### Technical Problem

A common semiconductor laser element has a region (LED region) that emits light (spontaneous emission light) by spontaneous emission by supplying a current to an active layer, and a region (LD region) that emits light (stimulated emission light) by stimulated emission by supplying a current equal to or greater than a threshold current. Photons are amplified by stimulated emission. Furthermore, stimulated emission is repeatedly executed by repeatedly reflecting light (stimulated emission light) generated by the stimulated emission by a mirror constituting a resonator. When an increase in energy due to the amplification of photons exceeds loss energy in the resonator, laser oscillation occurs and laser light is obtained.

FIG. 7 is a graph illustrating a relationship between a current supplied to the semiconductor laser element and an optical output. As illustrated in FIG. 7, when a current equal to or greater than the threshold current (Ith) is not supplied to the semiconductor laser element, a high optical output such as laser light cannot be obtained. Note that a light output is also generated in a region where the current is equal to or less than the threshold current (Ith) due to spontaneous emission light, and in this region, the semiconductor laser element operates like an LED.

It is known that a carrier concentration (N) in a semiconductor is represented by N=N₀ exp(−Eg/2kT) where Eg represents a band gap energy, T represents a temperature, and k represents a Boltzmann constant. In the equation, No is a constant. That is, in a low temperature environment where the value of T is small, the carrier concentration decreases, and thus a resistance component in the semiconductor layer increases. Therefore, in order for the semiconductor laser element to emit laser light, a larger voltage needs to be applied. The threshold current (Ith) has temperature dependency and decreases with a decrease in temperature, but the decrease in the threshold current is negligibly small as compared with the increase in the resistance component.

In particular, a semiconductor laser element that emits high-energy laser light, such as blue or blue-violet laser light, using a GaN-based material has a deeper energy level than a semiconductor laser element that emits red laser light using a GaAs-based material, and thus there is a case where carriers cannot be ensured until the stimulated emission light enters the active layer.

That is, in order to emit laser light from the semiconductor laser element in a low temperature environment, it is necessary to apply a higher voltage than in the case of using the semiconductor element in a room temperature environment. However, when a high voltage is suddenly applied to the semiconductor laser element, the semiconductor laser element may be destroyed by application of an overvoltage, heat generation due to a resistance component, local current concentration, destruction of an end surface due to abnormality of light output, or the like.

Therefore, in many commercially available semiconductor laser elements, particularly semiconductor laser elements using GaN-based materials, the upper limit value of a range of applicable voltage is defined so as not to cause the above-described defect, and a guaranteed operating temperature range is defined around 0° C. to 65° C. In addition, it is confirmed that, as a semiconductor laser element using a GaAs-based material, there is an element in which the lower limit value of a guaranteed operating temperature is lowered to −10° C.

Conventionally, a semiconductor laser element is mainly used for devices used in a room such as a projector and lighting equipment, so that the semiconductor laser element is operated in a range of 5° C. to 40° C. at most. Therefore, the above-described problem does not particularly occur.

However, as described above, a lighting device using a semiconductor laser element that can be used in a low temperature environment such as a cold region has been studied. In particular, an environment in which the temperature is lower than 0° C. and further an environment in which the temperature is lower than −10° C. are out of the guaranteed operating temperature range of the conventional semiconductor laser element, and applying a high voltage for forcibly outputting laser light may destroy the semiconductor laser element.

In view of the above problems, an object of the present invention is to provide a lighting device using a semiconductor laser element that can be safely used even in a cold region or the like.

### Solution to Problem

A lighting device according to the present invention includes:

a plurality of semiconductor laser elements;

a temperature sensor that measures an ambient temperature of the plurality of semiconductor laser elements; and

a current controller that controls current supply to the semiconductor laser elements, wherein,

when a measured value from the temperature sensor is equal to or less than a predetermined first threshold temperature, the current controller does not supply a current equal to or greater than a threshold current, which is required to emit laser light, to the semiconductor laser elements until the measured value exceeds the first threshold temperature, and

when the measured value exceeds the first threshold temperature, the current controller supplies a current equal to or greater than the threshold current to the semiconductor laser elements.

According to the above configuration, the temperature of the semiconductor laser elements or the atmospheric temperature around the semiconductor laser elements is measured by the temperature sensor that measures the ambient temperature of the plurality of semiconductor laser elements. The current controller does not supply a current equal to or greater than the threshold current until the temperature measured by the temperature sensor exceeds the predetermined first threshold temperature.

Therefore, there is a low possibility that the semiconductor laser elements are destroyed by application of overvoltage, heat generation due to a resistance component, local current concentration, destruction of end surfaces due to abnormality of light output, and the like. Thus, the lighting device can be safely operated. Here, the predetermined first threshold temperature is set to, for example, a lower limit value of a guaranteed operating temperature range defined for the semiconductor laser elements to be used.

Usable examples of the temperature sensor include a thermistor, a thermocouple, a semiconductor temperature sensor, and a radiation thermometer. The temperature sensor may be disposed to measure any temperature such as the temperature of a substrate on which the semiconductor laser elements are mounted or the atmospheric temperature at a position away from the semiconductor laser elements by a predetermined distance, as long as the temperature sensor can measure the temperature without causing a large error from the temperature of the semiconductor laser elements.

In the lighting device,

the first threshold temperature may be 0° C. or higher.

In a commercially available semiconductor laser element that emits light in a visible light region, a guaranteed operating temperature range is often defined around −10° C. to 0° C. Therefore, if control is performed such that a current is supplied after it is confirmed that the temperature exceeds at least 0° C., the guaranteed operating temperature range of the semiconductor laser element is kept, and thus, the lighting device can be operated more safely.

The lighting device may include

a heater, and when the measured value from the temperature sensor is lower than a predetermined second threshold temperature equal to or lower than the first threshold temperature, the heater may heat the semiconductor laser elements.

With the above configuration, when the measured value from the temperature sensor is below the second threshold temperature in an environment with a temperature below the predetermined first threshold temperature, the temperature of the semiconductor laser elements can be forcibly and quickly raised to the first threshold temperature. Here, the predetermined second threshold temperature is set to, for example, a lower limit value of a guaranteed operating temperature range defined for the semiconductor laser elements to be used. Note that the first threshold temperature and the second threshold temperature may be set to the same temperature.

It is to be noted that, when the measured value from the temperature sensor reaches a predetermined temperature equal to or higher than the first threshold temperature, heating by the heater may be stopped. According to such a configuration, the semiconductor laser elements are heated by the heater only when the temperature falls below the second threshold temperature, and thus, it is possible to prevent the semiconductor laser elements from being unnecessarily heated by the heater during a normal operation or when the operation is started in an indoor environment, for example. The predetermined temperature at which the heater is stopped can be set to a temperature greater than the first threshold temperature by about 10 to 20° C.

In the lighting device,

when the measured value from the temperature sensor is lower than the predetermined second threshold temperature, the current controller may supply a current equal to or lower than the threshold current to the semiconductor laser elements.

In the semiconductor laser elements, laser oscillation does not occur, but a current equal to or lower than the threshold current can be passed therethrough. Then, when a current equal to or lower than the threshold current is passed, the semiconductor laser elements self-heat according to the resistance component.

By using the self-heating of the semiconductor laser elements, it is possible to raise the temperature of the semiconductor laser elements forcibly and quickly to the first threshold temperature without additionally using a heating mechanism such as a heater when the measured value from the temperature sensor is below the second threshold temperature in an environment with a temperature below the predetermined first threshold temperature.

In the lighting device,

when the measured value from the temperature sensor is lower than the second threshold temperature, the current controller may supply a current to the semiconductor laser elements so that the current gradually increases within a range equal to or lower than the threshold current.

As described above, when a current equal to or lower than the threshold current is passed through the semiconductor laser elements, laser oscillation does not occur, but the current can flow therethrough. However, when, for example, a current close to the threshold current or a high voltage is rapidly supplied, rapid heat generation due to the resistance component or local current concentration may occur, and the semiconductor laser elements may be destroyed.

Therefore, the current supplied to the semiconductor laser elements gradually increases as described above, by which the occurrence of rapid heat generation due to the resistance component and local current concentration can be suppressed, and the operation of the lighting device can be started more safely.

In the lighting device,

the second threshold temperature may be 0° C. or lower.

When the lighting device is configured to perform control such that a current is supplied after it is confirmed that the temperature exceeds at least 0° C. as described above, the guaranteed operating temperature range of the semiconductor laser element is kept, and thus, the operation of the lighting device can be started more safely.

The lighting device may be configured such that

a value of total power supplied to the semiconductor laser elements may be 300 W or more.

With the above configuration, a high-output light source device can be achieved, and such a light source device can be used in a scene where a high-output lighting device is required, such as for construction or railway inspection performed in darkness, for example, at night or in a tunnel.

In the lighting device,

the semiconductor laser elements may be nitride semiconductor light emitting elements.

As described above, in a nitride semiconductor light emitting element which is a semiconductor laser element using a GaN-based material (GaN, InGaN, AlGaN, AlInGaN, etc.) or the like, a carrier concentration tends to decrease and a resistance value tends to increase under a low temperature environment. Therefore, it is highly likely that the semiconductor laser elements are destroyed by the above-described defect.

According to the configuration of the present invention, a current equal to or greater than the threshold current is not supplied at least at the first threshold temperature or lower, and thus, the current is supplied only in a temperature range in which the semiconductor laser elements can be driven without any problem. Therefore, the lighting device according to the present invention has a low risk of destroying the semiconductor laser elements, and can also adopt a nitride semiconductor light emitting element as a light source.

### Advantageous Effects of Invention

According to the present invention, a lighting device using a semiconductor laser element that can be safely used even in a cold region or the like can be obtained.

### BRIEF DESCRIPTION OF DRAWINGS

FIG. 1 is a schematic diagram illustrating an example of a use mode of a lighting device.

FIG. 2 is a schematic overall perspective view of a lighting device according to one embodiment.

FIG. 3 is a schematic overall perspective view of the lighting device illustrated in FIG. 2 as viewed from another direction.

FIG. 4 is a cross-sectional view of the lighting device illustrated in FIG. 2 as viewed from a Z direction toward an emission window.

FIG. 5 is a cross-sectional view of the lighting device illustrated in FIG. 2 as viewed in an X direction.

FIG. 6 is a cross-sectional view of a lighting device according to one embodiment as viewed in the X direction.

FIG. 7 is a graph illustrating a relationship between a current supplied to a semiconductor laser element and an optical output.

### DESCRIPTION OF EMBODIMENTS

The lighting device according to the present invention will be described below with reference to the drawings. The drawings referred to below are all schematic, and dimensional ratios or numbers in the drawings do not necessarily coincide with the actual dimensional ratios or numbers.

### First Embodiment

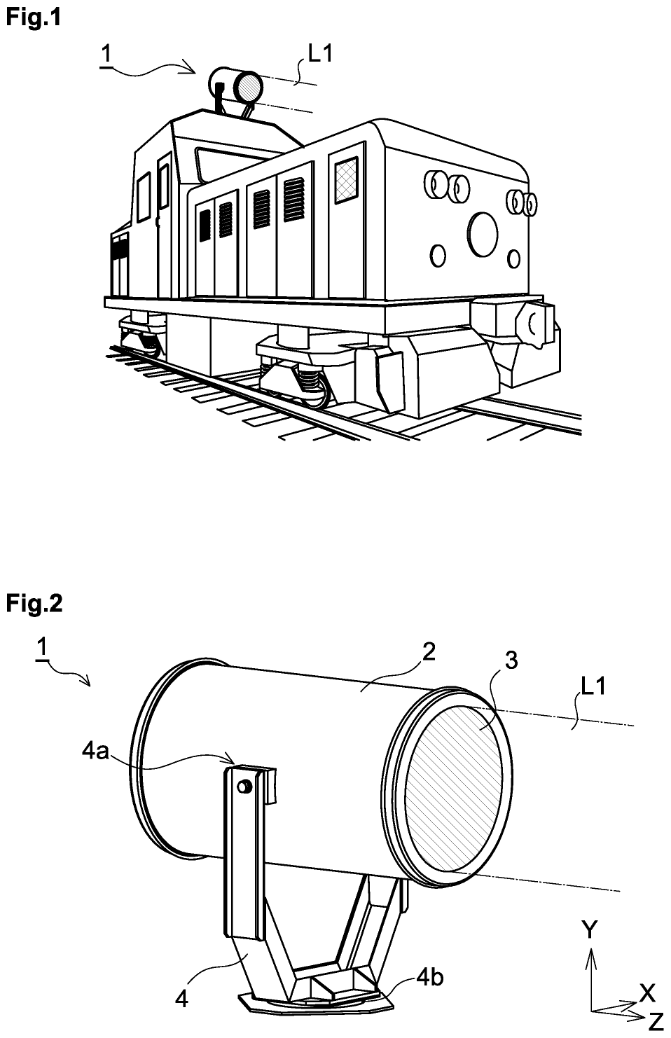

FIG. 1 is a schematic diagram illustrating an example of a use mode of a lighting device 1. A vehicle illustrated in FIG. 1 is an inspection vehicle that travels on a railway and inspects the railway for any abnormalities in a midnight zone when operation of a train, a bullet train, or the like is finished. The inspection performed using the inspection vehicle is mainly carried out such that an inspection worker in the inspection vehicle conducts visual inspection while traveling the inspection vehicle on the railway.

Therefore, the lighting device 1 mounted on the inspection vehicle needs to be bright enough to visually confirm an abnormality or the like of the railway ahead at midnight, and therefore, the lighting device 1 is required to have a high output. The lighting device 1 according to the present invention includes many semiconductor laser elements for achieving a high output, and is provided with a large current controller for supplying a large current. Therefore, as illustrated in FIG. 1, the entire device is very large.

Note that a value of total power supplied to semiconductor laser elements 10 of the lighting device 1 used for midnight inspection or the like as illustrated in FIG. 1 is preferably at least 300 W or more. In addition, when the lighting device 1 is used for a light source that projects light over a long distance, such as a lighthouse, a value of total power supplied to the semiconductor laser elements 10 is preferably at least 600 W or more.

FIG. 2 is a schematic overall perspective view of the lighting device 1 according to one embodiment. As illustrated in FIG. 2, the lighting device 1 according to the first embodiment includes a cylindrical casing 2, an emission window 3 for emitting light L1 from the casing 2, and a support base 4 for fixing the lighting device 1.

In the following description, a vertical direction is defined as a Y direction, a direction in which the light is emitted is defined as a Z direction, and a direction orthogonal to the Y direction and the Z direction is defined as an X direction. In addition, regarding directions, when positive and negative directions are distinguished from each other, each of the directions is indicated herein with positive or negative sign such as “+Z direction” or “−Z direction”. On the other hand, when the direction is expressed without distinction between positive and negative directions, the direction is simply referred to as “Z direction”.

The casing 2 includes therein a plurality of semiconductor laser elements (semiconductor laser elements 10 to be described later) as a light source, and emits light L1 from the emission window 3. The shape of casing 2 is not limited a cylindrical shape, and may have an elliptical cylindrical shape or a rectangular cylindrical shape, or a conical shape, a pyramid shape that expands toward the emission window 3, and the emission window 3 may also have an elliptical shape or a polygonal shape.

As illustrated in FIG. 1, the support base 4 is a base for fixing the lighting device 1 to a vehicle or the like. The support base 4 includes a first rotation part 4a for rotating the casing 2 about the X direction, and a second rotation part 4b for rotating the casing 2 about the Y direction. As a result, the emission window 3 can be directed in any direction, and the light L1 can be emitted in any direction.

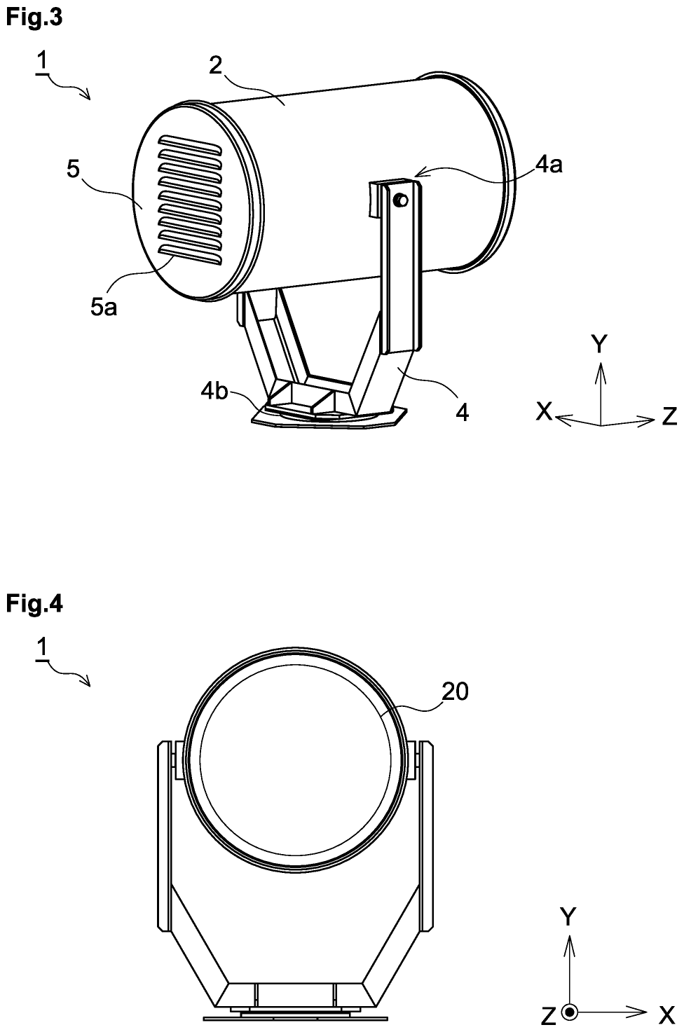

FIG. 3 is a schematic overall perspective view of the lighting device 1 illustrated in FIG. 2 as viewed from another direction. As illustrated in FIG. 3, a cover 5 having a heat release opening 5a for releasing high-temperature air from the inside of the casing 2 is provided on the side opposite to the emission window 3 of the casing 2.

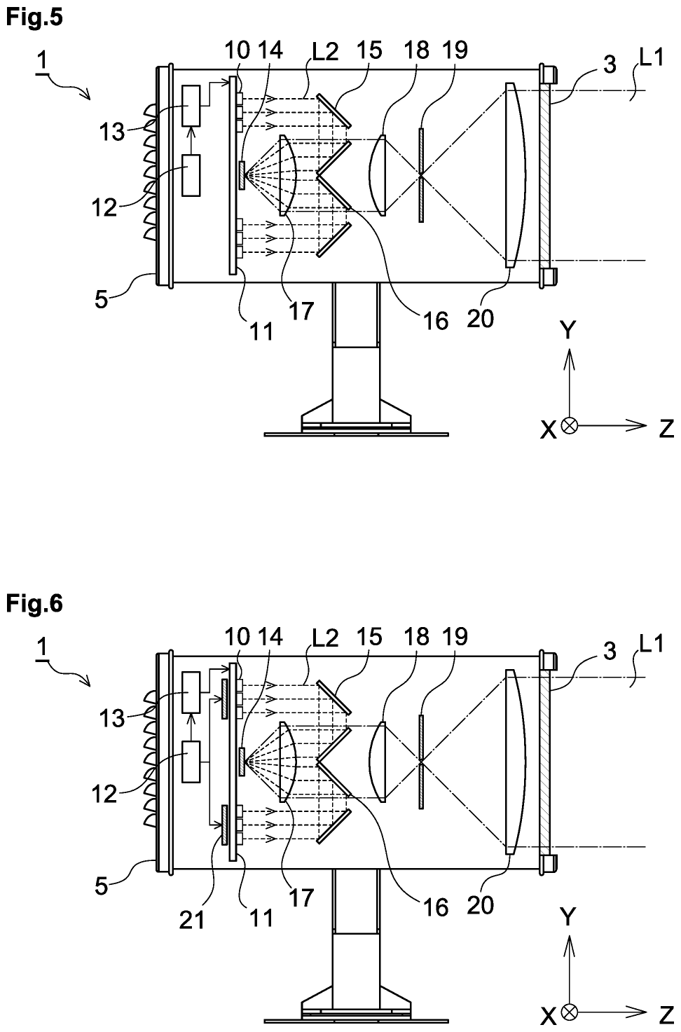

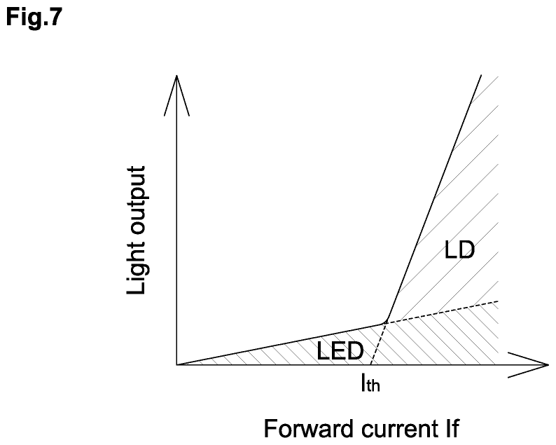

FIG. 4 is a cross-sectional view of the lighting device 1 illustrated in FIG. 2 as viewed from the Z direction toward the emission window 3. FIG. 5 is a cross-sectional view of the lighting device 1 illustrated in FIG. 2 as viewed in the X direction. As illustrated in FIGS. 4 and 5, the lighting device 1 includes, in the casing 2, a substrate 11 on which a plurality of semiconductor laser elements 10 is placed, a temperature sensor 12, a current controller 13, a phosphor 14, a mirror 15 for guiding laser light L2 emitted from the semiconductor laser elements 10 to the phosphor 14, a dichroic mirror 16, a first condenser lens 17 and a second condenser lens 18 for emitting the light L1 emitted from the phosphor 14 as parallel light from the emission window 3, an aperture 19, and a collimator lens 20.

In the first embodiment, the semiconductor laser elements 10 are an excitation light source that emits excitation light for generating fluorescence from the phosphor 14. The plurality of semiconductor laser elements 10 is disposed on the substrate 11 in order to obtain the lighting device 1 with high output, that is, in order to obtain high-output light L1 from the phosphor 14. For example, in the lighting device 1 used for midnight inspection as illustrated in FIG. 1, about several tens to several hundreds of semiconductor laser elements 10 are disposed so that the value of total power supplied to the semiconductor laser elements 10 is 300 W or more as described above.

Note that the semiconductor laser elements 10 in the first embodiment are nitride semiconductor light emitting elements, and are light emitting elements that emit the laser light L2 in a visible light region. In this configuration, a fluorescent agent may be applied to the emission surfaces of the semiconductor laser elements 10.

The laser light L2 emitted from the semiconductor laser elements 10 is reflected by the mirror 15 and the dichroic mirror 16, and enters the first condenser lens 17. The laser light L2 entering the first condenser lens 17 is condensed toward the phosphor 14 disposed at the focal position of the first condenser lens 17. When the condensed laser light L2 enters the phosphor 14, the phosphor 14 emits light L1 that is fluorescence.

The light L1 emitted from the phosphor 14 is collimated by the first condenser lens 17 and enters the second condenser lens 18. The light L1 entering the second condenser lens 18 is converted so as to be condensed toward a small opening 19a of the aperture 19 disposed at the focal position of the second condenser lens 18.

The light L1 that has passed through the opening 19a of the aperture 19 travels like light emitted from a point light source. Therefore, the light L1 that has passed through the opening 19a of the aperture 19 enters the collimator lens 20 and is emitted as parallel light from the emission window 3 toward the outside of the casing 2. In this way, the lighting device capable of projecting light over a long distance with high output is achieved. Note that the lighting device 1 may not include the phosphor 14, and may collimate the laser light L2 emitted from the semiconductor laser elements 10 and directly emit the collimated laser light from the emission window 3.

The temperature sensor 12 in the first embodiment is disposed on a side opposite to the surface of the substrate 11 where the semiconductor laser elements 10 are disposed so as not to block the travel of the laser light L2 emitted from the semiconductor laser elements 10, and measures the ambient temperature of the semiconductor laser elements 10. The temperature sensor 12 outputs a voltage, a current, or a signal corresponding to the measured temperature value to the current controller 13.

As illustrated in FIG. 5, the temperature sensor 12 in the first embodiment is disposed at a position away from the casing 2 and the substrate 11, but may be disposed so as to be in contact with the casing 2 and the substrate 11, or may be disposed on a side portion of the substrate 11 or the like.

When receiving a signal based on the value of the temperature measured by the temperature sensor 12, the current controller 13 controls current supply to the semiconductor laser elements 10 according to the measured value. More specifically, in a case where the measured value from the temperature sensor 12 exceeds a first threshold temperature T1, the current controller 13 performs control to supply a current equal to or greater than a threshold current necessary for emitting the laser light L2 to the semiconductor laser elements 10. Here, the first threshold temperature T1 is preferably set to a value of 0° C. or higher.

As described above, in many of the semiconductor laser elements 10 using a GaN-based material, the guaranteed operating temperature range is set to 0° C. to 65° C. That is, when a current equal to or greater than the threshold current is supplied under an environment at a temperature lower than 0° C., the semiconductor laser elements 10 may be destroyed.

On the other hand, the current controller 13 included in the lighting device 1 performs control to supply a current equal to or greater than the threshold current only when the measured value from the temperature sensor 12 is equal to or greater than the first threshold temperature T1, preferably equal to or greater than 0° C., that is, to keep the guaranteed operating temperature range of the semiconductor laser elements 10. Thus, the destruction of the semiconductor laser elements 10 can be suppressed.

In the first embodiment, in a case where the measured value from the temperature sensor 12 is below a second threshold temperature T2, the current controller 13 performs control to supply a current equal to or less than the threshold current to the semiconductor laser elements 10. Even if the current less than the threshold current, the current that is sufficient not cause laser oscillation flows to the semiconductor laser elements 10. Therefore, the semiconductor laser elements 10 self-heat by the current flowing therethrough.

By utilizing this phenomenon, when the measured value from the temperature sensor 12 is lower than the second threshold temperature T2 in an environment with a temperature lower than the first threshold temperature T1, a current equal to or less than the threshold current is passed through the semiconductor laser elements 10 to cause self-heating, whereby the semiconductor laser elements 10 can be heated to a temperature higher than the first threshold temperature T1. That is, due to self-heating of the semiconductor laser elements 10, the temperature of the semiconductor laser elements 10 can be forcibly and quickly raised to the first threshold temperature T1 without using a separate heating device or the like.

With the above configuration, the lighting device 1 does not supply a current equal to or greater than the threshold current at the first threshold temperature T1 or lower, and there is no possibility of destroying the semiconductor laser elements 10 even in an environment with a low temperature equal to or lower than the first threshold temperature T1. Therefore, the safe lighting device 1 using the semiconductor laser elements 10 as a light source is achieved. In addition, the lighting device 1 includes a means for heating the semiconductor laser elements 10 to the first threshold temperature T1 or higher, and thus, the lighting device 1 can operate so as to keep the guaranteed operating temperature range of the semiconductor laser elements 10 in a cold region.

### Second Embodiment

Regarding a configuration of a lighting device 1 according to a second embodiment of the present invention, portions different from the first embodiment will be mainly described below.

FIG. 6 is a cross-sectional view of the lighting device 1 according to one embodiment as viewed in the X direction. As illustrated in FIG. 6, the lighting device 1 according to the second embodiment includes a heater 21 for heating the semiconductor laser elements 10. The heater 21 is in contact with the surface of the substrate 11.

The heater 21 heats the semiconductor laser elements 10 via the substrate 11 when the measured value from the temperature sensor 12 is lower than the second threshold temperature T2 during operation of the lighting device 1. As a result, the temperature of the semiconductor laser elements 10 can be forcibly and quickly raised to the first threshold temperature T1.

Note that, as the heater 21, a ceramic heater, a silicon rubber heater, a space heater, a Peltier element, or the like can be used, for example. Although the heater 21 in the second embodiment is disposed in contact with the substrate 11 as illustrated in FIG. 6, the heater 21 may be disposed at a position away from the substrate 11, or may be disposed in contact with an inner wall surface of the casing 2 etc.

With the above configuration, the lighting device 1 can also operate in compliance with the guaranteed operating temperature range of the semiconductor laser elements 10 in a cold region.

### Another Embodiment

Hereinafter, another embodiment is described.

<1> The lighting device 1 may be heated with a stove, an air conditioner, a dryer, or the like so that the temperature of the semiconductor laser elements 10 exceeds the first threshold temperature T1. While the temperature of the semiconductor laser elements 10 exceeds the first threshold temperature T1 and a current equal to or greater than the threshold current is supplied, the temperature equal to or higher than the first threshold temperature T1 can be maintained by self-heating. Therefore, upon startup, the lighting device 1 only needs to be heated until reaching a temperature higher than the first threshold temperature T1, and after that, the lighting device 1 does not need to be heated from outside.

While a current equal to or greater than the threshold current is supplied to the semiconductor laser elements 10, a high-temperature state may be caused by self-heating. Therefore, the lighting device 1 may include a heat sink for releasing heat generated by the self-heating to the semiconductor laser elements 10. The heat sink is disposed on the surface of the substrate 11, for example.

<2> The above-described lighting device 1 can be used even in a normal temperature environment, and is not limited to be used in a low temperature environment.

<3> The configuration of the lighting device 1 is merely an example, and the present invention is not limited to each of the illustrated configurations.

### REFERENCE SIGNS LIST

1 Lighting device
2 Casing
3 Emission window
4 Support base
4a First rotation part
4b Second rotation part
5 Cover
5a Heat release opening
10 Semiconductor laser element
11 Substrate
12 Temperature sensor
13 Current controller
14 Phosphor
15 Mirror
16 Dichroic mirror
17 First condenser lens
18 Second condenser lens
19 Aperture
20 Collimator lens
21 Heater
L1 Light
L2 Laser light
T1 First threshold temperature
T2 Second threshold temperature

1. A lighting device comprising:
a plurality of semiconductor laser elements;
a temperature sensor that measures an ambient temperature of the plurality of semiconductor laser elements; and
a current control unit that controls current supply to the semiconductor laser elements, wherein,
when a measured value from the temperature sensor is equal to or less than a predetermined first threshold temperature, the current control unit does not supply a current equal to or greater than a threshold current, which is required to emit laser light, to the semiconductor laser elements until the measured value exceeds the first threshold temperature, and
when the measured value exceeds the first threshold temperature, the current control unit supplies a current equal to or greater than the threshold current to the semiconductor laser elements.

2. The lighting device according to claim 1, wherein the first threshold temperature is equal to or greater than 0° C.

3. The lighting device according to claim 1, comprising a heater, wherein,
when the measured value from the temperature sensor is lower than a predetermined second threshold temperature, the heater heats the semiconductor laser elements.

4. The lighting device according to claim 1, wherein, when the measured value from the temperature sensor is lower than a predetermined second threshold temperature, the current control unit supplies a current equal to or less than the threshold current to the semiconductor laser elements.

5. The lighting device according to claim 4, wherein, when the measured value from the temperature sensor is lower than the second threshold temperature, the current control unit supplies a current to the semiconductor laser elements so that the current gradually increases within a range equal to or less than the threshold current.

6. The lighting device according to claim 3, wherein the second threshold temperature is equal to or lower than 0° C.

7. The lighting device according to claim 1, wherein a value of total power supplied to the semiconductor laser elements is 300 W or more.

8. The lighting device according to claim 1, wherein the semiconductor laser elements are nitride semiconductor light emitting elements.

9. The lighting device according to claim 2, comprising a heater, wherein,
when the measured value from the temperature sensor is lower than a predetermined second threshold temperature, the heater heats the semiconductor laser elements.

10. The lighting device according to claim 2, wherein, when the measured value from the temperature sensor is lower than a predetermined second threshold temperature, the current control unit supplies a current equal to or less than the threshold current to the semiconductor laser elements.

11. The lighting device according to claim 3, wherein, when the measured value from the temperature sensor is lower than a predetermined second threshold temperature, the current control unit supplies a current equal to or less than the threshold current to the semiconductor laser elements.

12. The lighting device according to claim 9, wherein, when the measured value from the temperature sensor is lower than a predetermined second threshold temperature, the current control unit supplies a current equal to or less than the threshold current to the semiconductor laser elements.

13. The lighting device according to claim 10, wherein, when the measured value from the temperature sensor is lower than the second threshold temperature, the current control unit supplies a current to the semiconductor laser elements so that the current gradually increases within a range equal to or less than the threshold current.

14. The lighting device according to claim 11, wherein, when the measured value from the temperature sensor is lower than the second threshold temperature, the current control unit supplies a current to the semiconductor laser elements so that the current gradually increases within a range equal to or less than the threshold current.

15. The lighting device according to claim 12, wherein, when the measured value from the temperature sensor is lower than the second threshold temperature, the current control unit supplies a current to the semiconductor laser elements so that the current gradually increases within a range equal to or less than the threshold current.

16. The lighting device according to claim 4, wherein the second threshold temperature is equal to or lower than 0° C.

17. The lighting device according to claim 5, wherein the second threshold temperature is equal to or lower than 0° C.

18. The lighting device according to claim 9, wherein the second threshold temperature is equal to or lower than 0° C.

19. The lighting device according to claim 10, wherein the second threshold temperature is equal to or lower than 0° C.

20. The lighting device according to claim 11, wherein the second threshold temperature is equal to or lower than 0° C.
